(19) United States
(12) Patent Application Publication
(10) Pub. No.: US 2002/0158306 A1
(43) Pub. Date: Oct. 31, 2002

(54) Semiconductor device with a spiral inductor

(76) Inventor: Yoichiro Niitsu, Kanagawa-ken (JP)

Correspondence Address: Pillsbury Winthrop LLP, Intellectual Property Group, 725 South Figueroa Street, Suite 2800, Los Angeles, CA, 90017-5406, US

(21) Appl. No.: 10/036,314

(22) Filed: Dec. 26, 2001

(30) Foreign Application Priority Data
Dec. 26, 2000 (JP) P2000-396081

(51) Int. Cl. H01L 29/00

(52) U.S. Cl. 257/531

(57) ABSTRACT

A first semiconductor device includes a first conductive layer, a second conductive layer located above or below the first conductive layer, and an insulating layer interposed between the first conductive layer and the second conductive layer, a spiral inductor having a spiral pattern that is formed in the first conductive layer, and an electromagnetic wave shield formed in a plane shape in the second conductive layer. The electromagnetic wave shield is grounded or connected to a constant voltage source and is located above or below the spiral inductor. Furthermore the first semiconductor device includes an opening formed in the electromagnetic wave shield. The opening is located in a region corresponding to a region above or below a central region of the spiral pattern of the spiral inductor. A second semiconductor device includes a first conductive layer, a second conductive layer located above or below the first conductive layer, an insulating layer interposed between the first conductive layer and the second conductive layer, a spiral inductor having a spiral pattern that is formed in the first conductive layer, and an electromagnetic wave shield formed in a plane shape in the second conductive layer. The electromagnetic wave shield is grounded or connected to a constant voltage source and is located above or below the spiral inductor. Furthermore the second semiconductor includes a slit formed in the electromagnetic wave shield. The slit extends from a position of the electromagnetic wave shield, the position corresponding to a region above or below a center of the spiral inductor, to a peripheral direction of the electromagnetic wave shield.

### CROSS REFERENCE TO RELATED APPLICATION

This application is based upon and claims the benefit of priority from the prior Japanese Patent Application No. 2000-396081 filed on Dec. 26, 2000, the entire contents of which are incorporated herein by reference.

### BACKGROUND OF THE INVENTION

1. Field of the Invention

The present invention relates to a semiconductor device, more particularly to a semiconductor device provided with a spiral inductor and an electromagnetic wave shield.

2. Description of the Related Art

An inductor is an essential part required for an analog circuit or a radio frequency (RF) circuit. Recently, in many cases, the inductor has been formed of a thin film and mounted mixedly with other parts on the same board in order to reduce parts count.

As such a thin film inductor, for example, there are an inductor in which a plane spiral pattern is formed in any of wiring layers, an inductor in which a plurality of wiring layers and conductive plugs between the respective wiring layers are connected to each other to form a three-dimensional coil, and the like.

Among them, the spiral inductor having a plane spiral pattern has been often used. Because the number of required wiring layers including drawn electrode portions is small and a structure thereof is simple since an inductor portion is constituted of a single wiring layer. Also a resistance of the inductor can be reduced since the number of connection portions is small.

However, on the other hand, since a winding pattern is formed on a plane in the spiral inductor, a relatively broad occupation area is required. Accordingly, a cross talk signal such as an electromagnetic wave generated in other circuits easily flow into the spiral inductor, thus a circuit causes an incorrect action. Since there has been increased recently the case where a digital circuit is mounted mixedly with the analog circuit on the same board, an influence of the electromagnetic wave generated in the digital circuit and the like has come not to be ignorable. Therefore, examination has been made for a structure including, as well as the spiral inductor, some electromagnetic wave shielding means for inhibiting inflow of the cross talk signal. For example, examination is made for the use of a simple structure including a conductor layer as an electromagnetic wave shield above the spiral inductor.

FIG. 1A and FIG. 1B show an example of the spiral inductor and the simple electromagnetic wave shielding structure, which are formed on a semiconductor substrate 100.

As shown in FIG. 1A, for example, a spiral inductor 200 has a rectangular spiral pattern. For providing an electric current to the spiral pattern, electrodes are drawn respectively from a start point of the spiral pattern on the innermost turn and an end point thereof on the outermost turn. An electromagnetic wave shield 600 is grounded and has an area enough to cover an inductor portion of the spiral inductor 200, and as shown in FIG. 1B, is provided above the inductor with an insulating layer 150 interposed therebetween.

With regard to a characteristic of the inductor, it is desirable that a Q value be high. The higher a value of self-inductance (L) is, and the lower a value of resistance (R) is, a high Q value can be obtained.

The electromagnetic wave shield 600 exerts an effect of inhibiting the inflow of the cross talk signal from other circuits. On the other hand, due to an electromagnetic induction effect as described later, the electromagnetic wave shield 600 is likely to be a factor of lowering the self-inductance (L) of the spiral inductor 200, resulting in deterioration of the Q value.

In general, when an electric current flows into a wiring having a winding pattern, a magnetic field is generated by a circular current. This magnetic field shows the highest magnetic flux density in a center of the circular current. Also in the case of the spiral inductor 200, similarly, a magnetic flux in a direction perpendicular to the spiral surface of the spiral inductor 200 is generated on a center of the spiral pattern thereof as shown in FIG. 1B when an electric current flows into the spiral inductor 200. This magnetic flux penetrates the electromagnetic wave shield 600 placed above the spiral inductor 200. Since the electromagnetic shield 600 is a conductor, if the magnetic flux penetrating the electromagnetic shield 600 changes, an induced current flows like a swirl around the magnetic flux in the electromagnetic wave shield 600 due to the electromagnetic induction effect. This induced current generated by the electromagnetic induction is generated in a direction where the change in magnetic flux is inhibited. Therefore, the induced current lowers the magnetic flux density generated by the spiral inductor 200, thus reduces the self-inductance (L) and deteriorates the Q value.

For solving this problem, in the gazettes of the U.S. Pat. Nos. 5,969,590 and 5,831,331, disclosed is a method for preventing generation of an induced current, in which an electromagnetic wave shield having a pattern coincident with a pattern of principal turns of a spiral inductor is provided. However, in accordance with this method, it is difficult to obtain a sufficient electromagnetic wave shielding effect since a large number of gaps are provided in the electromagnetic wave shield.

### SUMMARY OF THE INVENTION

A semiconductor device according to a first aspect of the present invention includes a spiral inductor having a spiral pattern formed of a first conductive layer and a plane electromagnetic wave shield formed of a second conductive layer, the electromagnetic wave shield being located above or below the first conductive layer with an insulating layer interposed therebetween. This electromagnetic wave shield is grounded or connected to a constant voltage source, and has an opening in a region above or below a central region of the spiral pattern of the spiral inductor.

A semiconductor device according to a second aspect of the present invention includes a spiral inductor having a spiral pattern formed of a first conductive layer and a plane electromagnetic wave shield formed of a second conductive layer, the electromagnetic wave shield being located above or below the first conductive layer with an insulating layer interposed therebetween. This electromagnetic wave shield is grounded or connected to a constant voltage source, and has a slit extending from a region of the electromagnetic wave shield above or below a central region of the spiral inductor to a peripheral direction of the electromagnetic wave shield

### BRIEF DESCRIPTION OF THE DRAWINGS

FIG. 1A and FIG. 1B are a partial plan view and a partial sectional view of a semiconductor device including a conventional spiral inductor and a conventional electromagnetic wave shield.

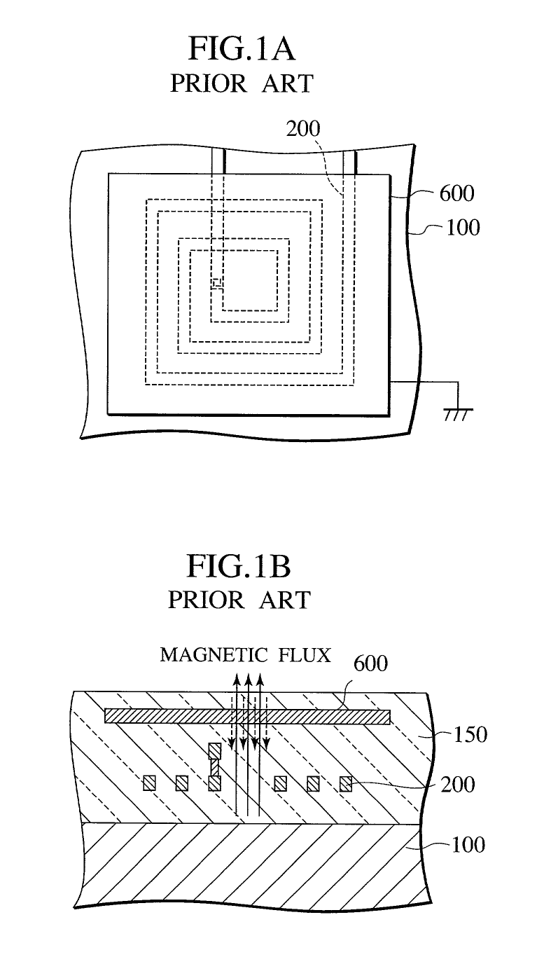

FIG. 2A and FIG. 2B are a partial plan view and a partial sectional view of a semiconductor device including a spiral inductor and an electromagnetic wave shield according to a first embodiment.

FIG. 3A and FIG. 3B are a partial plan view and a partial sectional view of a semiconductor device including a spiral inductor and an electromagnetic wave shield according to a second embodiment.

FIG. 4A and FIG. 4B are a partial plan view and a partial sectional view of a semiconductor device including a spiral inductor and two electromagnetic wave shields according to a third embodiment.

FIG. 5A and FIG. 5B are partial plan views of semiconductor devices, each including a spiral inductor and an electromagnetic wave shield according to a fourth embodiment.

FIG. 6A, FIG. 6B and FIG. 6C are partial plan views of semiconductor devices according to a fifth embodiment, showing configuration examples of various slits formed in the electromagnetic wave shields.

### DETAILED DESCRIPTION OF THE EMBODIMENTS

Hereinafter, description will be made for embodiments of the present invention with reference to the drawings.

### First Embodiment

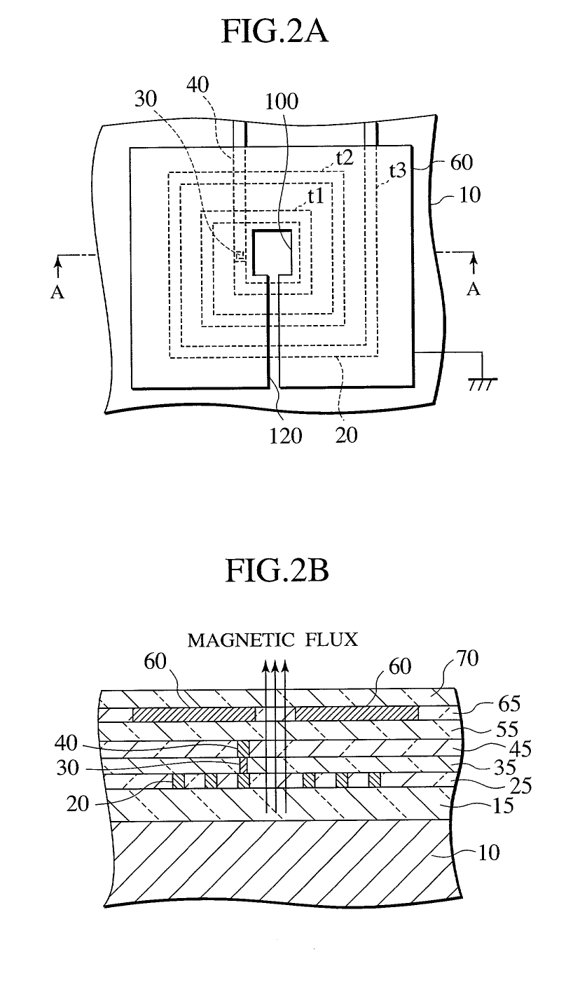

FIG. 2A is a plan view showing a first embodiment of a semiconductor device of the present invention, and FIG. 2B is a sectional view taken along a break line A-A in FIG. 2A.

As shown in FIG. 2A, the semiconductor device according to the first embodiment includes a spiral inductor 20 having a spiral pattern formed on the same plane and an electromagnetic wave shield 60. For example, a spiral pattern is shown here, which has first, second and third turns t1, t2 and t3 from the inside. The electromagnetic wave shield 60 has an opening 100 in a region above an approximately central region of the spiral pattern of the spiral inductor 20 and has a slit 120 extending from this opening 100 to a peripheral portion of the electromagnetic wave shield 60.

Hereinafter, description will be made more concretely for a constitution of each portion.

A formation position of the spiral inductor is not particularly limited, and the spiral inductor may be formed of any of wiring layers. For example, as shown in FIG. 2B, the spiral inductor can be formed of a first wiring layer. In this case, in the first wiring layer on a first interlayer insulation film 15 formed on a semiconductor substrate 10, the spiral inductor 20 having a spiral pattern as shown in FIG. 2A is formed.

As a wiring layer forming the spiral inductor 20, any wiring layer including widely used Al wiring can be used as long as it is a wiring layer. However, in order to increase a Q value of the spiral inductor 20, it is desirable to suppress resistance of the spiral inductor 20 itself as much as possible. Accordingly, it is desirable to use metal wiring having low resistance, particularly, Cu wiring.

As a size of the spiral pattern, an appropriate size can be selected in accordance with each circuit. However, for example, in the case of forming a spiral inductor 20 having an occupation area of 100 μm square, a line width of the spiral may be set wide to some extent, for example, in a range of 5 μm to 10 μm, and a line pitch may be set at about 10? m in order to suppress the resistance of the inductor as much as possible. In FIG. 2A, the spiral pattern composed of three turns is shown for the sake of convenience. However the number of turns may be selected according to needs. Note that, preferably, a thickness of the spiral be rather thick to some extent in order to lower the resistance. For example, in the case of using a Cu wiring layer, it is desirable to set a thickness thereof at about 2 μm to 4 μm.

In the spiral inductor 20, electrodes are drawn respectively from a start point of a turn on a center of the spiral and an end point of the turn on the outermost spiral. For example, as shown in FIG. 2B, as the drawn electrode line from the start point of the turn, an electrode 40 and a conductive via 30 are formed in a second wiring layer and in a second interlayer insulating film 35 therebetween respectively, and thus the electrode 40 is drawn to the outside of the spiral inductor 20. Moreover, a drawn electrode line from the end point of the turn may be formed in the first wiring layer constituting the spiral inductor.

Meanwhile, the electromagnetic wave shield 60 is formed in a third wiring layer on a third interlayer insulating film 55. As shown in FIG. 2A, it is desirable that the electromagnetic wave shield 60 have an area enough to cover the spiral inductor 20 in order to exert a sufficient electromagnetic wave shielding effect for the spiral inductor 20. Since the electromagnetic wave shield 60 may be anything that can shield a magnetic wave, the electromagnetic wave shield 60 may be formed of any material as long as it is a conductor. The electromagnetic wave shield 60 is connected to a ground potential by a drawn electrode line (not shown). Note that the electromagnetic wave shield 60 may be connected not to the ground potential but to a constant voltage source.

One feature of the electromagnetic wave shield 60 according to the first embodiment is that the opening 100 is defined in the central region of the electromagnetic wave shield 60 immediately above a region surrounded by a first turn t1 that is a spiral pattern located on the innermost side of the spiral inductor 20.

As shown in FIG. 2B, since a winding current flows in the spiral when an electric current is provided in the spiral inductor 20, a magnetic flux caused from this winding current is generated in the center of the spiral. This magnetic flux shows the highest magnetic flux density in the center of the spiral and is generated in a direction perpendicular to a spiral formation surface.

The opening 100 formed in the electromagnetic wave shield 60 may be somewhat overlapped with the first turn t1 of the spiral inductor 20. However, in order to prevent lowering of the electromagnetic wave shielding effect, preferably, the opening 100 should be formed in a portion as central as possible in a rectangular region surrounded by the first turn t1 so as not to overreach the rectangular region, and the opening 100 should have an area, for example, from about 50% to 90%, preferably about 80%, of an area of the rectangular region. Specifically, when the rectangular region surrounded by the first turn t1 that is the innermost spiral pattern is 10 μm square, it is desirable to set a size of the opening 100 at, for example, about 8 μm square.

The opening 100 is provided in the center of the electromagnetic wave shield 60, whereby the magnetic flux formed in the center of the spiral inductor 20 will almost pass through the opening 100. When a magnetic flux passes through a conductor, an induced current is generated around the magnetic flux by electromagnetic induction accompanied with a change in intensity of the magnetic flux. However, since the opening 100 is not a conductor, the induced current is no longer generated by the magnetic flux passing through the opening 100. Consequently, generation of a magnetic flux reverse to the magnetic flux by the spiral inductor 20, which has been hitherto generated by the induced current generated in the electromagnetic wave shield 60, is drastically reduced. Accordingly, attenuation of the self-inductance (L) of the spiral inductor 20 is suppressed, and the deterioration of the Q value thereof can be prevented.

Moreover, another feature of the electromagnetic wave shield 60 according to the first embodiment is that the electromagnetic wave shield 60 has the slit 120 from the opening 100 to the peripheral portion of the electromagnetic wave shield 60.

This slit 120 cuts off a current path winding around the magnetic flux passing through the center of the electromagnetic wave shield 60. Accordingly, a width of the slit is not limited, and the slit may be anything that can form an electrically disconnecting portion. However, if the slit is too wide, leak of the electromagnetic wave is likely to be caused therefrom. Therefore, it is desirable to cut a slit as thin as possible, for example, thinner than the line width of the spiral inductor, preferably, 5 to 6 μm or less.

Even if the magnetic flux partially passes through the conductor that is the electromagnetic wave shield 60, due to the existence of the slit 120, a current path that will be a closed loop is not formed around the partial magnetic flux. Thus a winding induced current is not generated, therefore, the magnetic flux reverse to the magnetic flux of the spiral inductor 20 is not generated. Hence, the self-inductance (L) of the spiral inductor 20 is not attenuated, and the deterioration of the Q value can be prevented.

Note that the spiral inductor 20 and the electromagnetic wave shield 60 according to the first embodiment can be formed by use of a manufacturing method generally used for manufacturing a semiconductor device. For example, the spiral inductor 20 and the electromagnetic wave shield 60 may be formed by use of, for example, a damascene process or a dual damascene process as described below. Hereinafter, description will be made for an example of a fabrication method thereof with reference to FIG. 2B.

For example, when the spiral inductor 20 and the electromagnetic wave shield 60 are formed of Cu wiring layers, the insulating film 25 is formed on the first interlayer insulating film 15 formed on the semiconductor substrate 10. Furthermore, on this insulating film 25, a trench corresponding to the spiral pattern and the drawn electrode portions of the spiral inductor is formed by use of a photolithography process. A Cu wiring layer is formed on the surface of the substrate so as to be buried in the trench, and subsequently, the surface of the substrate is smoothened by use of a Chemical Mechanical Polishing (CMP) process, then the spiral inductor 20 is obtained.

Subsequently, the second interlayer insulating film 35 and the insulating film 45 are formed, and a trench pattern corresponding to the conductive via 30 and the drawn electrode line 40 is formed, which are formed at the start point of the spiral pattern of the spiral inductor 20. Thereafter, this trench pattern is buried with a wiring layer, and subsequently, the surface of the substrate is smoothened by use of the CMP process. Thus, the conductive via 30 and the drawn electrode line 40 are obtained.

Next, the third interlayer insulating film 55 is formed on the surface of the substrate, and the insulating film 65 is formed thereon. A trench is formed, which corresponds to the pattern of the electromagnetic wave shield having the opening 100 and the slit 120, then the surface of the substrate is coated with the Cu wiring layer so as to bury the Cu wiring layer in the trench, and the surface of the substrate is smoothened by the CMP process, thus the electromagnetic wave shield 60 is formed. Furthermore, the surface is covered with an insulating film 70 such as an interlayer insulating film or a passivation film, then a structure shown in FIG. 2A and FIG. 2B is obtained.

As described above, according to the semiconductor device of the first embodiment, the opening 100 and the slit 120 are formed in the electromagnetic wave shield 60, thus making it possible to suppress the generation of the magnetic flux, which is reverse to the magnetic flux by the spiral inductor and decrease the magnetic flux, in the electromagnetic wave shield 60. Accordingly, the influence of the electromagnetic wave can be prevented without deteriorating the Q value of the spiral inductor 20.

### Second Embodiment

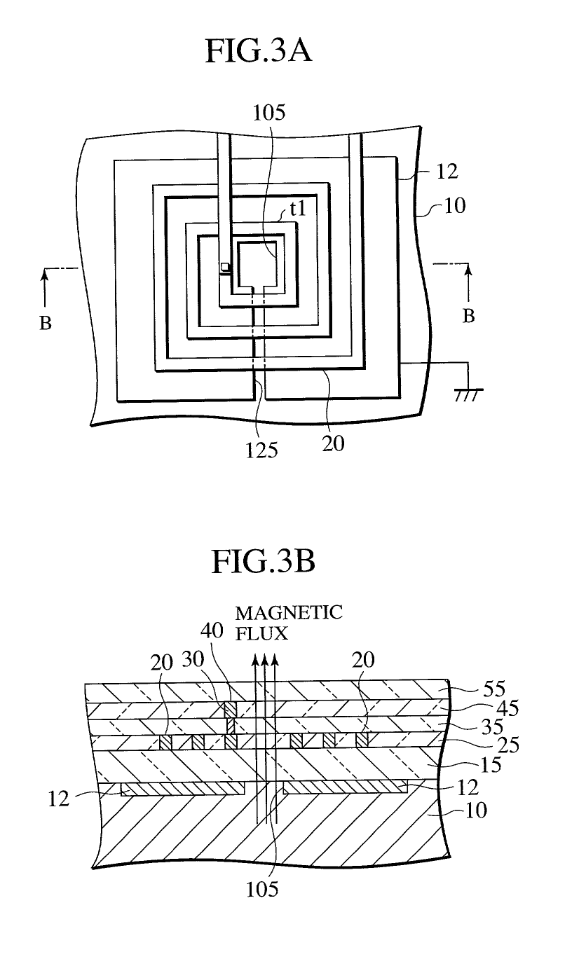

FIG. 3A is a plan view showing a second embodiment of the semiconductor device of the present invention, and FIG. 3B is a sectional view taken along a break line B-B in FIG. 3A.

Similarly to the first embodiment, also in the second embodiment, an electromagnetic wave shield has an opening in a region facing to an approximately central region of a spiral pattern of a spiral inductor, and has a slit reaching a peripheral portion of the electromagnetic wave shield from this opening. However, the second embodiment is different from the first embodiment in that the electromagnetic wave shield is formed below the spiral inductor.

As shown in FIG. 3A and FIG. 3B, similarly to the first embodiment, a first wiring layer on the first interlayer insulating film 15 formed on the semiconductor substrate 10 is patterned, and the spiral inductor 20 having a spiral pattern in a swirl shape is formed. As a size and a shape of the spiral inductor 20, the ones under approximately the same conditions as the ones according to the first embodiment can be used.

Meanwhile, the electromagnetic wave shield 12 according to the second embodiment is constituted of an impurity diffusion layer formed on an upper surface layer of the semiconductor substrate 10 as a semi-insulating layer. The impurity diffusion layer 12 is obtained, for example, by forming a pattern of a resist film covering a region where a diffusion layer is not formed on a substrate surface of the semiconductor substrate 10 such as an Si substrate and by doping impurity ions by use of an ion implantation method with the resist film taken as an implantation mask. The impurity to be doped may be any of the one contributing to the p-type and the one contributing to the n-type. For example, P, As or the like having five valences is doped thereto so that the impurity concentration can be 10¹⁹ cm⁻³ to 10²⁰ cm⁻³, then, is activated in an annealing process that follows, thus the impurity diffusion layer exhibits conductivity.

In the case of forming the electromagnetic wave shield 12 of the impurity diffusion layer as described above, the electromagnetic wave shield 12 can be formed simultaneously with a process for fabricating a source or drain region of a MOS transistor by use of a process for forming the MOS transistor to be formed on the same substrate.

Also in this case, provided are an opening 105 in a central region of the electromagnetic wave shield 12, which is corresponding to a region below the region surrounded by the first turn t1 located in the innermost side of the spiral pattern of the spiral inductor 20, and a slit 125 reaching the outer periphery of the electromagnetic wave shield 12 from the opening 105.

The opening 105 is provided in the electromagnetic wave shield 12, thus the magnetic flux formed in the center of the spiral inductor 20 will almost pass through the opening 105. Since there is a semi-insulating layer in the inside of the opening 105, an induced current is hardly generated by the magnetic flux passing therethrough. Consequently, it is possible to suppress lowering of the magnetic flux density in the spiral inductor, which has been hitherto caused by the induced current generated in the electromagnetic wave shield 12.

Moreover, the slit 125 reaching the outer periphery of the electromagnetic wave shield 12 from the opening 105 formed in the central portion inhibits formation of the current path winding the magnetic flux passing through the center of the electromagnetic wave shield 12. Therefore, the generation of the magnetic flux formed by the winding induced current can be suppressed. Accordingly, the generation of the magnetic flux can be suppressed, which is reverse to the magnetic flux by the spiral inductor 20 and decrease the magnetic flux without sacrificing the electromagnetic wave shielding effect of the electromagnetic wave shield 12. Therefore, the value of the self-inductance (L) of the spiral inductor is maintained, and the deterioration of the Q value can be prevented.

### Third Embodiment

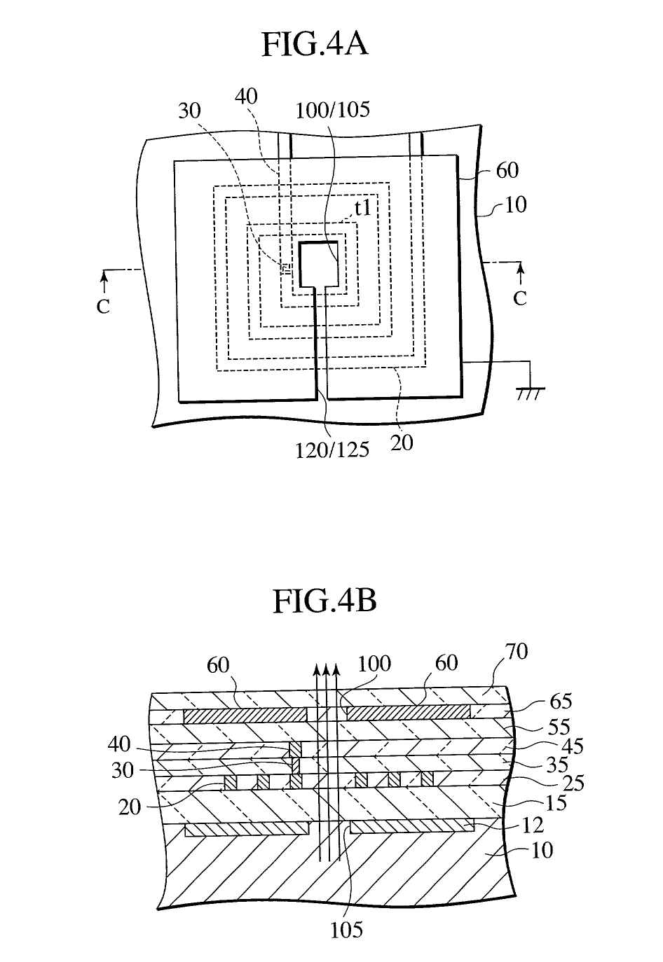

FIG. 4A is a plan view showing a third embodiment of the semiconductor device of the present invention, and FIG. 4B is a sectional view taken along a break line C-C in FIG. 4A.

Similarly to the first and second embodiments, also in the third embodiment, an electromagnetic wave shield has an opening in a central region of a spiral pattern of a spiral inductor, that is, in a region corresponding to a region above the region in the inside of the first turn t1 in the innermost side, and has a slit reaching a peripheral portion of the electromagnetic wave shield from this opening. However, the third embodiment is different from the first and second embodiments in that the electromagnetic wave shields are formed above and below the spiral inductor.

As shown in FIG. 4A and FIG. 4B, similarly to the first and second embodiments, in a first wiring layer on the first interlayer insulating film 15 formed on the semiconductor substrate 10, the spiral inductor 20 of a spiral pattern in a swirl shape as shown in FIG. 4A is formed. As a size and a shape of the spiral inductor 20, the ones under approximately the same conditions as the ones according to the first embodiment can be used.

An electromagnetic wave shield 60 to be located above the spiral inductor 20 is formed under the similar condition to the first embodiment, and an electromagnetic shield 12 to be located below the spiral inductor 20 is formed under the similar condition to the second embodiment. As described above, two layers of the electromagnetic wave shields are provided in the semiconductor device according to the third embodiment, and thus a higher shielding effect than those in the first and second embodiments can be provided.

By the openings 100 and 105 provided respectively on the centers of the electromagnetic wave shields 60 and 12, the magnetic flux formed in the center of the spiral inductor 20 will almost pass through the openings 100 and 105 located above and below the spiral inductor 20. Therefore, an induced current is hardly generated by the magnetic flux passing therethrough the inside of the opening 100. Consequently, the magnetic flux is reduced, which is reverse to the magnetic flux by the spiral inductor and has been hitherto caused by the induced currents generated in the electromagnetic wave shields 60 and 12.

Moreover, the slits 120 and 125, which reach the outer periphery of the electromagnetic wave shield from the respective openings 100 and 105 formed in the central portion, inhibits formation of the current path winding around the magnetic flux passing through the center of the electromagnetic wave shield. Therefore, the generation of another magnetic flux formed by the winding of the induced current can be suppressed. Accordingly, without sacrificing the respective electromagnetic wave shielding effects of the electromagnetic wave shields 60 and 12, the magnetic field of the inductor is maintained, and the deterioration of the Q value can be prevented.

Note that, while the electromagnetic wave shield 12 provided below the spiral inductor is formed of an impurity diffusion layer in the second and third embodiments, the electromagnetic wave shield 12 may be formed of a wiring layer. For example, the electromagnetic wave shield to be located below the spiral inductor may be formed of the first wiring layer, the spiral inductor may be formed of the second or third wiring layer, and the electromagnetic wave shield may be formed of a wiring layer located more above.

### Fourth Embodiment

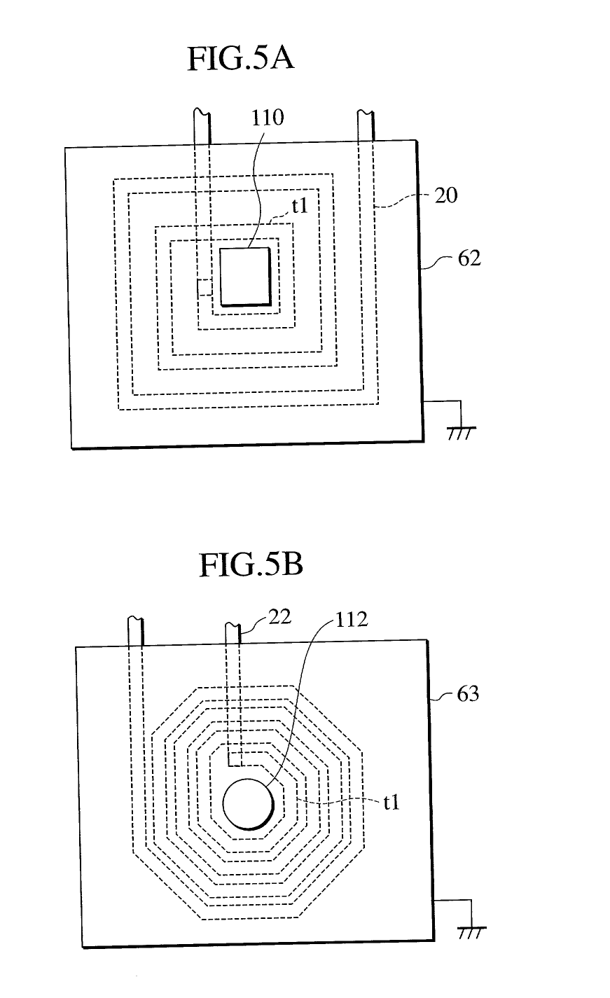

FIGS. 5A and 5B are plan views showing an electromagnetic wave shield and a spiral inductor, the plan views showing a fourth embodiment of the semiconductor device of the present invention. Note that, here, illustration of the semiconductor substrate and the like is omitted.

In the first to third embodiments, examples have been shown, in which both the opening and the slit are formed in the electromagnetic wave shield. However, there is still a great effect of suppressing the deterioration of the Q value of the spiral inductor even in the case of only forming the opening. Accordingly, an example is shown here, in which an electromagnetic wave shield only having an opening is used. Note that, while the case of providing the electromagnetic wave shield above the spiral inductor is exemplified, the electromagnetic wave shield may be located either above or below the spiral inductor as shown in the second and third embodiments.

For example, shown in FIG. 5A, an opening 110 is formed in a central region of a spiral pattern of the spiral inductor 20, that is, in a region on an electromagnetic wave shield 62, which corresponds to a region surrounded by the first turn t1 in the innermost side. When the magnetic flux generated in the spiral inductor 20 almost passes through the opening 110, the magnetic flux passing through the conductor is already reduced to a great extent, and an amount of the induced current generated by the passage of the magnetic flux through the conductor is also limited. Therefore, the generation of the magnetic flux reverse to the magnetic flux by the spiral inductor is suppressed, and the deterioration of the Q value of the spiral inductor can be prevented.

The shape of the opening formed in the electromagnetic wave shield is not particularly limited, and the opening may have any shape suitable to the spiral pattern of the spiral inductor. For example, as shown in FIG. 5B, when a spiral inductor 22 has a spiral pattern basically having an octagonal shape, an opening 112 to be formed in a center of an electromagnetic wave shield 63 may be formed in a circular shape or a polygonal shape close to the circular shape.

As shown in the fourth embodiment, when the opening is only formed in the electromagnetic wave shield, the shielding effect for the electromagnetic wave can be increased more than in the case of forming both the opening and the slit.

### Fifth Embodiment

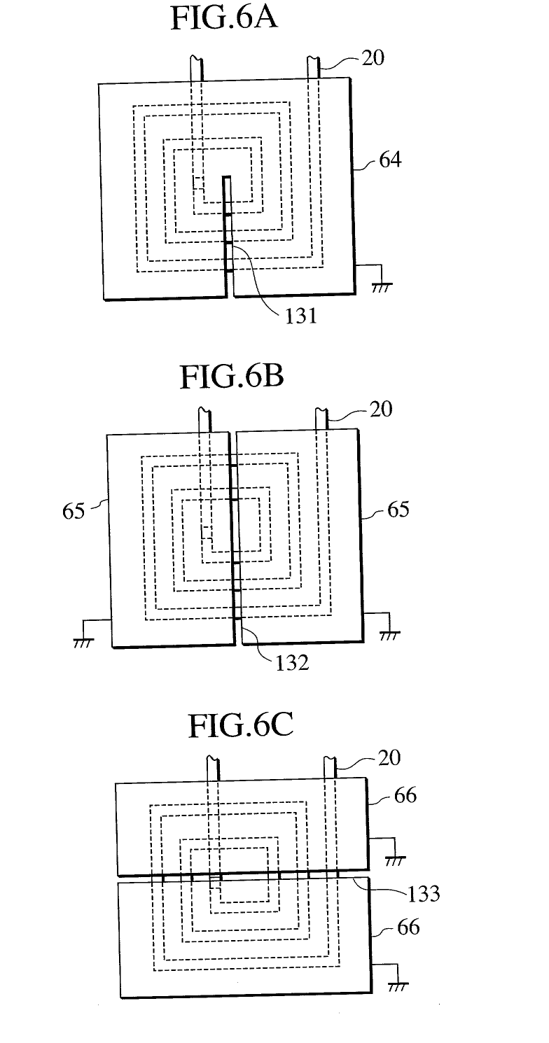

FIG. 6A to FIG. 6C are plan views showing electromagnetic wave shields and spiral inductors, the plan views showing a fifth embodiment of the present invention. Note that, here, illustration of the semiconductor substrate and the like is omitted. Note that, while the case of providing the electromagnetic wave shield above the spiral inductor is exemplified, the electromagnetic wave shield may be located either above or below the spiral inductor as shown in the second and third embodiments.

In the first to third embodiments, the example has been shown, in which both the opening and the slit are provided in the electromagnetic wave shield. However, only with the slit, there is still a great effect of suppressing the deterioration of the Q value of the spiral inductor. Even if the magnetic flux generated by the spiral inductor when an electric current flows in a conductor that is the electromagnetic wave shield, a slit is provided so that a closed current path cannot be formed around the magnetic flux, and thus a winding induced current is not generated. Therefore, the magnetic flux reverse to the magnetic flux of the spiral inductor by the induced current is not generated. Accordingly, with regard to the slit formed in the electromagnetic wave shield, formed may be a slit passing through a center of a magnetic flux generated by the spiral inductor when the magnetic flux passes through the electromagnetic wave shield and reaching the periphery of the electromagnetic shield. Alternatively, the slit may not completely reach the periphery of the electromagnetic wave shield, and at least, may extend to the periphery of the electromagnetic wave shield from the center of the magnetic flux.

For example, as shown in FIG. 6A, a slit 131 reaching a periphery of an electromagnetic wave shield from the center of the magnetic flux generated by the spiral inductor 20 may be formed. The slit 131 in this case has about a half length of one side of a rectangular plane of the electromagnetic wave shield 64. In accordance with the slit 131, an electromagnetic wave shielding effect of the electromagnetic wave shield 64 is hardly sacrificed.

Moreover, as shown in FIG. 6B, a slit 132 passing through the center of the magnetic flux generated in the spiral inductor 20 and completely dividing the electromagnetic wave shield 65 into two regions may be formed. In this case, in comparison with the case of FIG. 6A, the formation of a current path winding around the magnetic flux generated in the spiral inductor can be prevented more securely. Note that the two regions obtained by dividing the electromagnetic wave shield 65 by the slit are required to be connected to the ground potentials or the constant voltage sources, respectively.

Note that, with regard to the slit provided so as to pass through the center of the magnetic flux generated by the spiral inductor 20 and to completely divide the electromagnetic wave shield into two regions, a direction thereof is not particularly limited. As the slit 132 shown in FIG. 6B, the slit may be formed in a longitudinal direction in FIG. 6B. Alternatively, as a slit 133 shown in FIG. 6C, the slit may be formed in a lateral direction in FIG. 6C. Alternatively, the slit may be formed in a diagonal direction and other.

Moreover, the number of slits is not limited to one, but the smaller the number is, the more the sacrifice of the electromagnetic wave shielding effect is saved. Furthermore, it is desirable that a width of the slit be as narrow as possible.

Description has been made for the semiconductor device of the present invention along the embodiments. However, the present invention is not limited to the above description of the embodiments, and it is obvious to those skilled in the art that various improvements and substitutions of materials are enabled. For example, the plane pattern of the spiral inductor is not limited to a rectangle, and a variety of polygonal or circular spiral shapes can be adopted. Moreover, the electromagnetic wave shield is not only disposed above and below the spiral inductor, but also may be expanded to side surfaces of the spiral inductor and the like according to needs.

Note that the semiconductor device according to the above-described embodiments of the present invention can be applied to a semiconductor device having an analog circuit mixedly mounted thereon or a semiconductor device, on which a spiral inductor is required to be mounted, such as an RF circuit. Moreover, in a semiconductor device, on which a digital circuit or a voltage control oscillator (Vco) circuit is mixedly mounted, the influence of the electromagnetic wave is large, and thus the electromagnetic wave shield is required in the semiconductor device. Therefore, the above-described device structure of the present invention is extremely effective.

As described above, in the semiconductor device of the present invention, the opening is provided in the region of the electromagnetic wave shield, which corresponds to the region where the magnetic flux generated by the spiral inductor passes. Therefore, the generation of the winding current generated by the electromagnetic induction is suppressed, and the lowering of the density of the electromagnetic flux generated by the spiral inductor is suppressed, thus a good electromagnetic wave shielding effect can be exhibited without deteriorating the Q value.

Another semiconductor device of the present invention is provided with the slit extending to the peripheral portion from the center of the region where the magnetic flux generated by the spiral inductor passes in the electromagnetic wave shield. Therefore, the generation of the winding current is suppressed, and the lowering of the electromagnetic flux density generated by the spiral inductor is prevented, thus a good electromagnetic wave shielding effect can be exhibited without deteriorating the Q value.

What is claimed is:

1. A semiconductor device, comprising:
a first conductive layer;
a second conductive layer located above or below the first conductive layer;
an insulating layer interposed between the first conductive layer and the second conductive layer;
a spiral inductor having a spiral pattern, the spiral pattern being formed in the first conductive layer;
a first electromagnetic wave shield formed in a plane shape in the second conductive layer, the first electromagnetic wave shield being grounded or connected to a constant voltage source and being located above or below the spiral inductor; and
an opening formed in the first electromagnetic wave shield, the opening being located in a region corresponding to a region above or below a central region of the spiral pattern of the spiral inductor.

2. The semiconductor device according to claim 1,
wherein the opening is located in a region having a magnetic flux generated by the spiral inductor passing therethrough.

3. The semiconductor device according to claim 1,
wherein the spiral pattern has a plurality of turns, and
the opening is formed in an inside of a region of the first electromagnetic wave shield, the region corresponding to the region above or below a region surrounded by a first turn in an innermost side among the plurality of turns.

4. The semiconductor device according to claim 3,
wherein the opening has an opening area of 50% to 90% of an area of the region surrounded by the first turn.

5. The semiconductor device according to claim 1,
wherein the second conductive layer is a conductive layer obtained by diffusing an impurity into an upper layer of a semiconductor substrate.

6. The semiconductor device according to claim 1, further comprising:
a slit formed in the first electromagnetic wave shield, the slit extending from the opening toward a peripheral portion of the electromagnetic wave shield.

7. The semiconductor device according to claim 1, further comprising:
a third conductive layer located to sandwich the first conductive layer with the second conductive layer;
another insulating layer interposed between the first conductive layer and the third conductive layer;
a second electromagnetic wave shield formed in the third conductive layer, the second electromagnetic wave shield being grounded or connected to the constant voltage source and being located above or below the spiral inductor; and
an opening formed in the second electromagnetic wave shield, the opening being located in the region corresponding to the region above or below the central region of the spiral pattern of the spiral inductor.

8. The semiconductor device according to claim 7,
wherein any one of the second conductive layer and the third conductive layer is a conductive layer obtained by diffusing an impurity into an upper layer of a semiconductor substrate.

9. The semiconductor device according to claim 7,
wherein at least one of the first electromagnetic wave shield and the second electromagnetic wave shield has a slit extending from any of the openings thereof to any of peripheral portions of the electromagnetic wave shields thereof.

10. The semiconductor device according to claim 1,
wherein the semiconductor device has at least one of an analog circuit and an RF circuit, and
the spiral inductor is formed in at least one of the analog circuit and the RF circuit.

11. The semiconductor device according to claim 10,
wherein the semiconductor device further comprises a digital circuit.

12. A semiconductor device, comprising:
a first conductive layer;
a second conductive layer located above or below the first conductive layer;
an insulating layer interposed between the first conductive layer and the second conductive layer;
a spiral inductor having a spiral pattern, the spiral pattern being formed in the first conductive layer;
a first electromagnetic wave shield formed in a plane shape in the second conductive layer, the first electromagnetic wave shield being grounded or connected to a constant voltage source and being located above or below the spiral inductor; and
a slit formed in the first electromagnetic wave shield, the slit extending from a position of the first electromagnetic wave shield, the position corresponding to a region above or below a center of the spiral inductor, to a peripheral direction of the first electromagnetic wave shield.

13. The semiconductor device according to claim 12,
wherein the slit is formed to cut off a current path winding around a magnetic flux generated in a center of the spiral pattern of the spiral inductor in which an electric currents flows.

14. The semiconductor device according to claim 12,
wherein the slit passes through the position of the first electromagnetic wave shield, the position corresponding to the region above or below the center of the spiral inductor, and divides the first electromagnetic wave shield.

15. The semiconductor device according to claim 12,
wherein the second conductive layer is a conductive layer obtained by diffusing an impurity into an upper layer of a semiconductor substrate.

16. The semiconductor device according to claim 12, further comprising:
a third conductive layer located to sandwich the first conductive layer with the second conductive layer;
another insulating layer interposed between the first conductive layer and the third conductive layer;
a second electromagnetic wave shield formed in the third conductive layer, the second electromagnetic wave shield being grounded or connected to the constant voltage source and being located above or below the spiral inductor; and
a slit formed in the second electromagnetic wave shield, the slit extending from a position of the second electromagnetic wave shield, the position corresponding to a region above or below a center of the spiral inductor, to a peripheral direction of the second electromagnetic wave shield.

17. The semiconductor device according to claim 16,
wherein any one of the first conductive layer and the third conductive layer is a conductive layer obtained by diffusing an impurity into an upper layer of a semiconductor substrate.

18. The semiconductor device according to claim 12,
wherein the semiconductor device has any one of an analog circuit and an RF circuit, and
the spiral inductor is formed in any one of the analog circuit and the RF circuit.

19. The semiconductor device according to claim 18,
wherein the semiconductor device further comprises a digital circuit.
